(19) United States
(12) Patent Application Publication
(10) Pub. No.: US 2012/0126688 A1
(43) Pub. Date: May 24, 2012

(54) ELECTROLUMINESCENT DEVICE

(75) Inventors: Martin Richardson, Cambs (GB); Nalinkumar Patel, Cambridge (GB); Russell Lees, Ely, Cambridgeshire (GB); Angela Lees, Ely, Cambridgeshire (GB); Matthew Roberts, Cambridge (GB)

(73) Assignee: Cambridge Display Technology Limited, Cambridgeshire (GB)

(21) Appl. No.: 11/915,531

(22) PCT Filed: May 24, 2006
(86) PCT No.: PCT/GB06/01910

§ 371 Date: Jun. 17, 2008

(30) Foreign Application Priority Data
May 25, 2005 (GB) 0510721.4

(51) Int. Cl. H05B 33/14; B05D 5/06; B32B 3/30; H05B 33/10

(52) U.S. Cl. 313/504; 445/25; 427/162; 428/174

(57) ABSTRACT

An organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode; and an encapsulant disposed over the second electrode, wherein the second electrode and the encapsulant are transparent to light emitted by the light emitting layer, wherein a cavity is provided between the encapsulant and the second electrode, and wherein an anti-reflective coating is provided on at least one side of the encapsulant for reducing reflection of light emitted by the light emitting layer so as to improve out-coupling of light from the device, said anti-reflective coating being transparent to light emitted by the light emitting layer.

### FIELD OF INVENTION

The present invention relates to an organic electroluminescent device comprising an anti-reflective coating.

### BACKGROUND OF INVENTION

Organic electroluminescent devices are known, for example from PCT/WO/13148 and U.S. Pat. No. 4,539,507. Such devices generally comprise: a substrate 2; a first electrode 4 disposed over the substrate 2 for injecting charge of a first polarity; a second electrode 6 disposed over the first electrode 4 for injecting charge of a second polarity opposite to said first polarity; an organic light emitting layer 8 disposed between the first and second electrodes; and an encapsulant 10 disposed over the second electrode 6. In one arrangement shown in FIG. 1, the substrate 2 and first electrode 4 are transparent to allow light emitted by the organic light-emitting layer 8 to pass therethrough. Such an arrangement is known as a bottom-emitting device. In another arrangement shown in FIG. 2, the second electrode 6 and the encapsulant 10 are transparent so as to allow light emitted from the organic light emitting layer 8 to pass therethrough. Such an arrangement is known as a top-emitting device. In bottom emitting devices the encapsulant may be opaque. An example of such an encapsulant is a metal can. For top emitting devices the encapsulant must be transparent. Examples of transparent encapsulants include thin film encapsulants deposited on an upper surface of the top electrode and glass can encapsulation in which a sheet of glass is disposed over the organic light emitting device.

Variations of the above-described structure are known. The first electrode may be the anode and the second electrode may be the cathode. Alternatively, the first electrode may be the cathode and the second electrode may be the anode. Further layers may be provided between the electrodes and the organic light-emitting layer in order to aid charge injection and transport. The organic material in the light-emitting layer may comprise a small molecule, a dendrimer or a polymer and may comprise phosphorescent moieties and/or fluorescent moieties. The light-emitting layer may comprise a blend of materials including light emitting moieties, electron transport moieties and/or hole transport moieties. These may be provided in a single molecule or on separate molecules.

By providing an array of devices of the type described above, a display may be formed comprising a plurality of emitting pixels. The pixels may be of the same type to form a monochrome display or they may be different colours to form a multicolour display.

A problem with many electroluminescent devices is that much of the light emitted by organic light emitting material in the organic light-emitting layer does not escape from the device. The light may be lost within the device by scattering, internal reflection, wave guiding, absorption and the like. This results in a reduction in the efficiency of the device. Furthermore, these optical effects can lead to low image intensity, low image contrast, ghosting and the like resulting in poor image quality.

One way of increasing the amount of light which escapes from the device is to provide an anti-reflective coating in the device structure. WO 2004/044999 discloses a bottom-emitting device comprising an anti-reflective coating made of an organic polymer material containing mesopores disposed between the substrate and the lower electrode. The anti-reflection coating disclosed in WO 2004/044999 is for increasing the amount of light which escapes from a bottom-emitting device by uncoupling light emitted from the light-emitting layer into the transparent substrate. However, the applicants have found that a problem with incorporating an additional layer or additional layers of material near to the light-emitting layer is that the emission characteristics of the light emitting layer are altered due to near field optical effects such as quenching and cavity effects.

US 2004/0051950 discloses the use of an anti-reflection film applied to a surface of a monitor that uses an organic electroluminescent device to prevent the reflection of ambient light. Such anti-reflection films typically comprise a circular polarizer for absorbing ambient light which is reflected off the device structure. Circular polarizers also absorb a proportion of the light emitted by the light-emitting layer of the device. Furthermore, as circular polarizers comprise a linear polarizer and a ¼ wave plate, additional interfaces are provided which results in an increase in the internal reflection of light emitted by the light-emitting layer. As such, circular polarizers are not “anti-reflective coatings” as the term is used in the present specification in that they do not reduce reflections at the surface on which they are coated. Rather, circular polarizing films prevent reflection of ambient light from other surfaces of the device by absorb this reflected light. Such layers do not improve out-coupling of light from the device.

US 2004/0041518 discloses a bottom-emitting organic electroluminescent element in which an anti-reflection layer for preventing the reflection of ambient light by the top electrode layer is formed on the device glass substrate except in regions where the emissive layer is formed. Since this layer prevents the reflection of light by the second electrode layer, only the light from the emissive layer radiates outwards through the device glass substrate, improving the contrast of the organic EL display device. The anti-reflective coating comprises a black matrix for preventing transmission of light. This layer does not improve out-coupling of light from the device.

Thus the anti-reflection films disclosed in both US 2004/0041518 and US 2004/0051950 are for preventing reflection of ambient light so as to increase the contrast of the display. They do not improve out-coupling of light emitted from the light-emitting layer. In contrast, the anti-reflection coating disclosed in WO 2004/044999 is for increasing the amount of light which escapes from a bottom-emitting device by uncoupling light emitted from the light-emitting layer into the transparent substrate.

### SUMMARY OF INVENTION

It is an aim of the present invention to provide an organic electroluminescent device having increased optical output while avoiding problems due to near field optical effects.

According to the present invention there is provided an organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode; and an encapsulant disposed over the second electrode, wherein the second electrode and the encapsulant are transparent to light emitted by the light emitting layer, wherein a cavity is provided between the encapsulant and the second electrode, and wherein an anti-reflective coating is provided on at least one side of the encapsulant for reducing reflection of light emitted by the light emitting layer so as to improve out-coupling of light from the device, said anti-reflective coating being transparent to light emitted by the light emitting layer.

Such an arrangement provides a top-emitting device in which light emitted by the light-emitting layer passes out of the device through the transparent second electrode, the cavity and the transparent encapsulant. The anti-reflective coating reduces reflections at encapsulant interfaces. Furthermore, by separating the anti-reflective coating from the emitting structure by the cavity, the emission characteristics of the device due to near field optical effects are not affected by the provision of the anti-reflective coating. That is, the anti-reflective coating is provided at a sufficient distance from the light-emitting layer such that near field optical effects are avoided.

Preferably the anti-reflective coating is provided at an interface between the cavity and the encapsulant.

The provision of an anti-reflective layer at the interface between the cavity and the encapsulant prevents light emitted from the light-emitting layer from being internally reflected at this interface.

Preferably a further anti-reflective coating is provided on an outer surface of the encapsulant on an opposite side to the cavity. Provision of this anti-reflective coating prevents reflection at the interface between the encapsulant and air surrounding the device.

Preferably the cavity has a thickness of 10 μm or more. The provision of such a cavity has two functions: (1) to ensure that the anti-reflective coating is sufficiently spaced apart from the emitting structure that near field effects are avoided; and (2) to allow for variations in the position of the encapsulant layer during manufacture so as to prevent the encapsulant from impinging on the light-emitting structure leading to damage thereof. Variations in the position of the encapsulant will occur due to errors in the etching of cavities in an encapsulant sheet and variations in the thickness of the perimeter seal. Typically glue sealants have a thickness tolerance of approximately 10 μm+/−5 μm. The errors in the etching of cavities in the encapsulant are the order of a few microns.

In order to improve the light output from a device, the absorbance of the anti-reflective coating should be low otherwise any reduction in light loss at the interface due to refraction/reflection will be more than off-set by absorption. A coated encapsulant should transmit more light than an uncoated encapsulant.

Typically there is a 4% light loss from an encapsulant interface due to refraction/reflection. Accordingly, preferably the transmittance of the anti-reflective coating is 96% or more, more preferably 97% or more, more preferably still, 98% or more and most preferably 99% or more for the light emitted by the light-emitting layer.

The cavity may be filled with any transparent material. However, preferably the material is not rigid so as to prevent underlying layers from being damaged on application of the encapsulant. Accordingly, it is preferable that the cavity is filled with a gas or liquid or a deformable solid such as an elastomer. For ease of manufacture, the cavity is most preferably filled with a gas.

Preferably the gas filled void comprises an inert gas such as high purity nitrogen. This reduces device degradation and thus increases the lifetime of the device.

The encapsulant may be adhered to the substrate directly or indirectly (via, for example, the first electrode) to form a perimeter seal. The encapsulant may be adhered by an adhesive, a weld or the like. Preferably the perimeter seal comprises a getter material. Such materials absorb oxygen and moisture thus reducing device degradation and increasing the lifetime of the device.

The encapsulant may comprise a glass sheet or a plastic sheet. Glass sheets are preferable for rigid devices due to their inertness and their impermeability to air and moisture. Plastic sheets are useful for flexible devices.

For glass encapsulation, preferably the thickness of the glass encapsulant is in the range 0.1 to 1.1 mm.

According to an embodiment of the present invention there is provided an organic electroluminescent device as described herein comprising a plurality of pixels forming a display.

Preferably the display comprises a common substrate on which the plurality of pixels is disposed.

Preferably the display comprises a common encapsulant disposed over the plurality of pixels.

The display may comprise a plurality of first electrodes. In one arrangement the substrate comprises an active matrix back plane comprising a plurality of thin film transistors forming an active matrix display. In such an arrangement a single second electrode may be provided common to the plurality of pixels. In a typical active matrix backplane, the driving circuitry, such as the thin film transistors, are located on the same side of the substrate as the light emitting devices. In an alternative arrangement a plurality of first and second electrodes may be provided so as to form a passive matrix display.

According to a second aspect of the present invention there is provided a method of manufacturing an organic electroluminescent device comprising the steps: depositing at least one first electrode over a substrate; depositing an organic light-emitting material over the at least one first electrode; depositing at least one second electrode over the organic light-emitting material wherein the at least one first electrode, the organic light-emitting material and the at least one second electrode form a light-emitting structure; and adhering an encapsulant over the light-emitting structure, wherein the at least one second electrode and the encapsulant are transparent to light emitted by the light-emitting material, wherein a cavity is provided between the encapsulant and the light emitting structure, and wherein the encapsulant comprises an anti-reflective coating on at least one side for reducing reflection of light emitted by the light-emitting material, said anti-reflective coating being transparent to light emitted by the light emitting material.

Preferably the encapsulant comprises a cavity therein. This is preferrably formed by etching although other techniques may be utilized such as pressing or sandblasting. The anti-reflective coating may be deposited after etching the cavity. Preferably the encapsulant is adhered to the substrate directly or indirectly with, for example, glue.

According to a third aspect of the present invention there is provided a preform comprising a plurality of organic electroluminescent devices as described herein, the substrate and the encapsulant being common to the plurality of organic electroluminescent devices and wherein the encapsulant comprises a sheet having a plurality of cavities formed therein, the cavities corresponding to positions of the plurality of organic electroluminescent devices. Preferably, break lines are provided between the plurality of organic electroluminescent devices.

According to a fourth aspect of the present invention there is provided a method of manufacturing a plurality of organic electroluminescent devices from the preform as described herein, comprising breaking the preform. Preferably the preform is scribed prior to breaking.

According to a fifth aspect of the present invention there is provided a method of manufacturing a preform as described herein, wherein the anti-reflective coating is deposited on the encapsulant after forming the plurality of cavities therein. Preferably the encapsulant is adhered to the substrate directly or indirectly after the cavity forming and deposition steps. The encapsulant may be adhered to the substrate by glue lines disposed between the plurality of light-emitting structures. The plurality of cavities may be formed by etching the sheet.

According to a sixth aspect of the present invention there is provided an encapsulating sheet for an organic light-emitting display, the encapsulating sheet comprising a transparent sheet of material having a plurality of cavities in one side thereof for receiving organic light-emitting structures, the transparent sheet of material having an anti-reflective coating provided on at least one side thereof for reducing reflection of light from said at least one side.

Preferably, the antireflective coating is disposed on the side of the transparent sheet having the plurality of cavities therein. Advantageously, the antireflective coating is disposed in the cavities and not in the spaces between the cavities. This allows for better adhesion of the encapsulating sheet to the substrate in a device as no antireflective coating is provided on the transparent sheet at adhesion points for forming a perimeter seal. Furthermore, such an arrangement avoids the possibility of oxygen and water ingress through the antireflective coating at the perimeter seal of the device.

Advantageously, another antireflective coating is provided on the side of the transparent sheet opposite to the side having the cavities therein.

According to a seventh aspect of the present invention there is provided a use of an encapsulating sheet as herein described for manufacturing an organic light-emitting display device.

According to a eighth aspect of the present invention there is provided a method of manufacturing an encapsulating sheet for an organic light-emitting display, the method comprising the steps: forming a plurality of cavities in one side of a transparent sheet of material for receiving organic light-emitting structures; and coating at least one side of the transparent sheet of material with an anti-reflective coating for reducing reflection of light from said at least one side.

Preferably, the antireflective coating is deposited on the side of the transparent sheet having the plurality of cavities therein after forming the cavities. Advantageously, the antireflective coating is deposited in the cavities and not in the spaces between the cavities. Advantageously, another antireflective coating is deposited on the side of the transparent sheet opposite to the side having the cavities therein.

### BRIEF DESCRIPTION OF THE DRAWINGS

For a better understanding of the present invention and to show how the same may be carried into effect, embodiments of the present invention will now be described by way of example, with reference to the accompanying drawings, in which:

FIG. 1 shows a known structure of a bottom-emitting organic light-emitting device;

FIG. 2 shows a known structure of a top-emitting organic light-emitting device;

FIG. 3 shows an organic light emitting device according to an embodiment of the present invention;

FIG. 4 shows a portion of a display according to an embodiment of the present invention; and

FIG. 5 shows a portion of an encapsulating sheet for an organic light-emitting display according to an embodiment of the present invention.

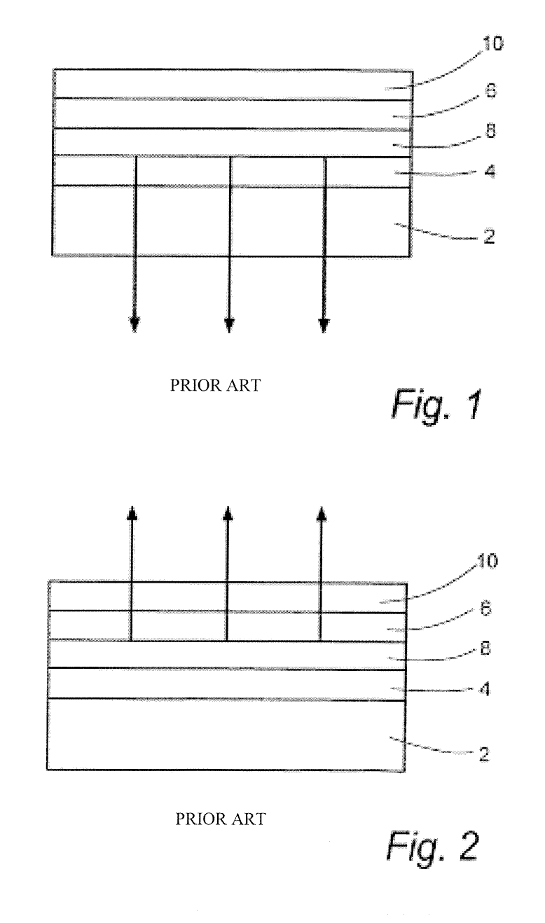

### DETAILED DESCRIPTION OF THE PREFERRED EMBODIMENT OF THE INVENTION

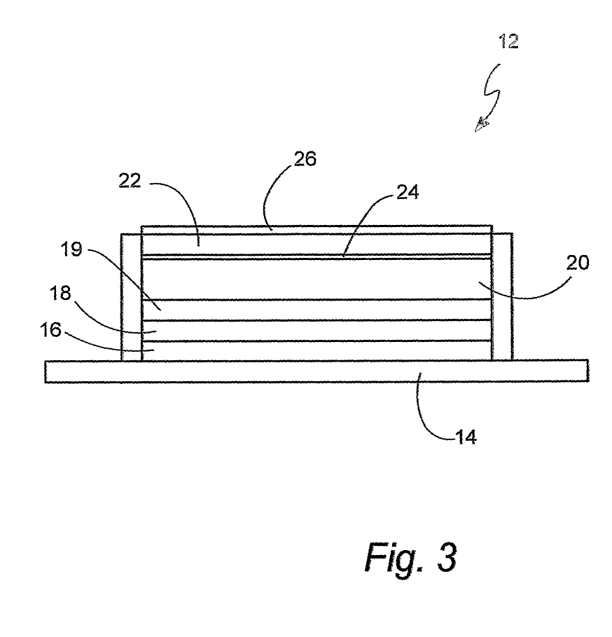

FIG. 3 shows an organic light-emitting device 12 according to an embodiment of the present invention. The device 12 comprises: a glass substrate 14; an anode 16 disposed thereover; a light-emitting polymer layer 18 disposed over the anode 16; a transparent cathode 19 disposed over the light emitting polymer 18; a gas void 20 disposed over the transparent cathode 19; and a glass can 22 encapsulating the aforementioned layers. An anti-reflective coating 24, 26 is provided on either side of the glass can encapsulant.

The thickness of the glass can 22 can be tuned to act as a spacer when both of the anti-reflective coatings 24, 26 are provided on either side of the glass can 22. In this case, the thickness of the glass can 22 is tuned to a thickness of around 5 to 12 micrometres, preferably 10 micrometres to outcouple or otherwise optimise the light output from the device. The anti-reflective coatings 24, 26 are therefore arranged to be separated by a distance of a few wavelengths.

The provision of anti-reflective coatings on a glass encapsulant with a gas filled cavity disposed between the glass encapsulant and the light emitting structure (electrodes and organic layers) enables the out-coupling of light to be decoupled from the light-emitting architecture. This decoupling has several different aspects as is discussed below.

The anti-reflective coating is decoupled from near field optical effects. By spacing the anti-reflective coatings apart from the light-emitting layer, out-coupling of light from the device is improved without affecting the emission properties of the device due to near field effects such as a change in frequency due to cavity effects or a reduction in emission intensity due to quenching effects.

The anti-reflective coating is decoupled from possible adverse chemical reactions with the other layers of the device. Processing of the anti-reflective coatings onto the glass enables standard anti-reflective coatings to be adopted without potentially adverse interaction with other layers of the device.

The provision of anti-reflective coatings is decoupled from the manufacturing method used for the device. The encapsulant comprising the anti-reflective coating can be prefabricated prior to device fabrication thus avoiding any increase in the complexity and cost of device fabrication.

Various types of anti-reflective coatings are suitable for the present invention. By spacing the anti-reflective coatings apart from the light-emitting architecture then the aforementioned problems are avoided. However, the anti-reflective coating should have a high transmittance for the wavelengths of light emitted by the light-emitting layer otherwise any increase in out-coupling of light due to a reduction in reflection will be off-set by an increase in absorption. Various anti-reflective coatings can be used in creating multilayer stacks and moth eye structures.

The anti-reflective coatings enable up to an 8% increase in the out-coupling of a top emitting organic light-emitting diode structure to be achieved. In addition, the reduction of optical reflection results in an image which does not suffer from ghosting.

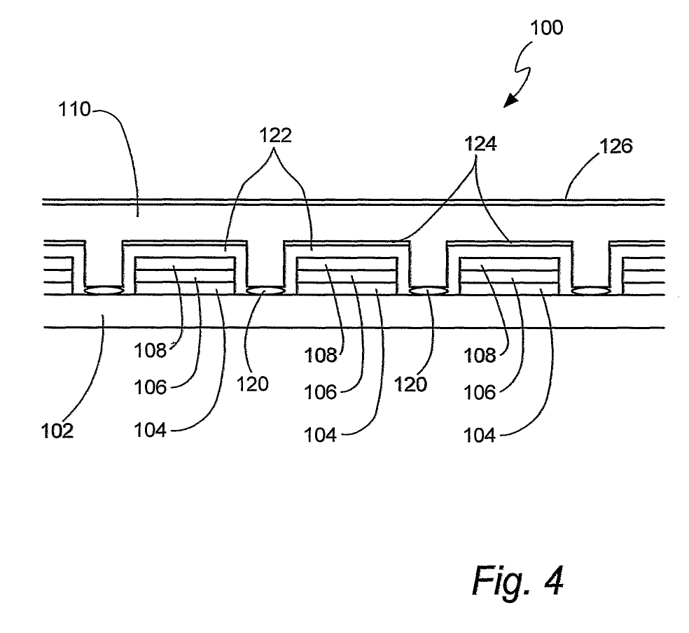

FIG. 4 shows a simplified schematic diagram illustrating a portion of a preform 100 for manufacturing a plurality of light emitting structures. The preform 100 comprises a common substrate 102 over which a plurality of anodes 104, organic electroluminescent material 106 and cathodes 108 are deposited to foam the plurality of light-emitting structures. A common encapsulant 110 is disposed over the light-emitting structures and is adhered to the substrate by lines of adhesive 120. The encapsulant 110 comprises a sheet having a plurality of cavities 122 formed therein, the cavities corresponding to the positions of the plurality of organic light-emitting structures. Anti-reflective coatings 124, 126 are provided on each side of the encapsulant for reducing reflection of light emitted from the light-emitting structures. The arrangement 100 is broken along lines between the plurality of light emitting structures so as to produce a plurality of devices. A more complex sealing structure (not shown) may be provided to allow for easier breaking. For example, lines of weakness may be provided by, for example, grooves and/or the arrangement may be scribed prior to breaking in a scribe and break process.

The light-emitting structures may comprise a single emitting component so as to form, for example, simple backlights. Alternatively, the light-emitting structures may comprise a plurality of pixels to form displays.

The preform 100 is manufactured by depositing the layers 104, 106, 108 to form the light-emitting structures on the substrate 102 and then adhering the prefabricated encapsulant sheet 110 thereover.

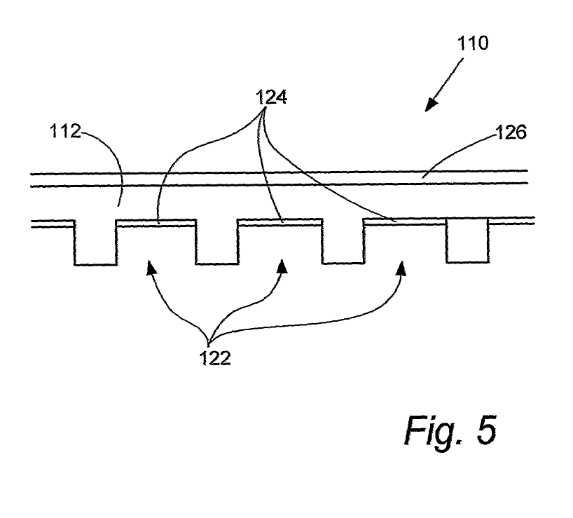

FIG. 5 shows a portion of the prefabricated encapsulating sheet 110 which comprises the transparent sheet of material 112 having the plurality of cavities 122 in one side thereof for receiving the organic light-emitting structures 104, 106, 108. The transparent sheet of material 112 has the anti-reflective coatings 124, 126 provided on each side thereof. The cavities 122 are formed by etching the transparent sheet 112 and the anti-reflective coatings 124, 126 are deposited on the encapsulant after the etching step. The antireflective coating 124 is disposed in the cavities but not in the spaces between the cavities. The encapsulant 110 is then adhered to the substrate 102 by glue lines 120 disposed between the plurality of light-emitting structures 104, 106, 108 as shown in FIG. 4.

While this invention has been particularly shown and described with reference to preferred embodiments, it will be understood to those skilled in the art that various changes in form and detail may be made without departing from the scope of the invention as defined by the appendent claims.

1. An organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode; and an encapsulant disposed over the second electrode, wherein the second electrode and the encapsulant are transparent to light emitted by the light emitting layer, wherein a cavity is provided between the encapsulant and the second electrode, and wherein an anti-reflective coating is provided on at least one side of the encapsulant for reducing reflection of light emitted by the light emitting layer so as to improve out-coupling of light from the device, said anti-reflective coating being transparent to light emitted by the light emitting layer.

2. An organic electroluminescent device according to claim 1, wherein the anti-reflective coating is provided at an interface between the cavity and the encapsulant.

3. An organic electroluminescent device according to claim 1, wherein two anti-reflective coatings are provided, one on each side of the encapsulant.

4. An organic electroluminescent device according to claim 3, wherein the encapsulant acts as a spacer between the two anti-reflective coatings such that the two anti-reflective coatings are separated by a distance of between 5 micrometers to 12 micrometers.

5. An organic electroluminescent device according to claim 1, wherein the cavity has a thickness of 10 μm or more.

6. (canceled)

7. An organic electroluminescent device according to claim 1, wherein the cavity is a gas filled cavity.

8. (canceled)

9. (canceled)

10. An organic electroluminescent device according to claim 1, wherein the encapsulant is adhered directly or indirectly to the substrate to form a perimeter seal comprising a getter material.

11. (canceled)

12. (canceled)

13. (canceled)

14. An organic electroluminescent device according to claim 1, wherein the thickness of the encapsulant is in the range 0.1 mm to 1.1 mm.

15. An organic electroluminescent device according to claim 1, comprising a plurality of pixels forming a display.

16. An organic electroluminescent device according to claim 15, wherein the substrate is common to the plurality of pixels.

17. An organic electroluminescent device according to claim 15, wherein the encapsulant is common to the plurality of pixels.

18. (canceled)

19. (canceled)

20. (canceled)

21. (canceled)

22. A method of manufacturing an organic electroluminescent device comprising: depositing at least one first electrode over a substrate; depositing an organic light-emitting material over the at least one first electrode; depositing at least one second electrode over the organic light-emitting material wherein the at least one first electrode, the organic light-emitting material and the at least one second electrode form a light-emitting structure; and adhering an encapsulant over the light-emitting structure, wherein the at least one second electrode and the encapsulant are transparent to light emitted by the light-emitting material, wherein a cavity is provided between the encapsulant and the light emitting structure, and wherein the encapsulant comprises an anti-reflective coating on at least one side for reducing reflection of light emitted by the light-emitting material, said anti-reflective coating being transparent to light emitted by the light emitting material.

23. A method according to claim 22, wherein the encapsulant comprises a cavity and is adhered to the substrate directly or indirectly to form a perimeter seal, the cavity and the perimeter seal having a depth such that the cavity is maintained.

24. A method according to claim 22, wherein the light emitting structure comprises a plurality of pixels forming a display.

25. A method according to claim 24, wherein the substrate is common to the plurality of pixels.

26. A method as claimed in claim 24, wherein the encapsulant is common to the plurality of pixels.

27. (canceled)

28. (canceled)

29. (canceled)

30. (canceled)

31. A preform comprising a plurality of organic electroluminescent devices according to claim 1, the substrate and the encapsulant being common to the plurality of organic electroluminescent devices and wherein the encapsulant comprises a sheet having a plurality of cavities formed therein, the cavities corresponding to positions of the plurality of organic electroluminescent devices.

32. A preform according to claim 31, comprising break lines provided between the plurality of organic electroluminescent devices.

33. A method of manufacturing a plurality of organic electroluminescent devices from the preform of claim 31, comprising breaking the preform.

34. (canceled)

35. A method of manufacturing a preform of claim 31, comprising depositing the anti-reflective coating on the encapsulant after forming the plurality of cavities therein.

36. (canceled)

37. A method of according to claim 35, comprising forming the plurality of cavities by etching the sheet.

38. An encapsulating sheet for an organic light-emitting display, the encapsulating sheet comprising a transparent sheet of material having a plurality of cavities in one side thereof for receiving organic light-emitting structures, the transparent sheet of material having an anti-reflective coating provided on at least one side thereof for reducing reflection of light from said at least one side.

39. An encapsulating sheet according to claim 38, wherein the antireflective coating is disposed on the side of the transparent sheet having the plurality of cavities therein.

40. An encapsulating sheet according to claim 39, wherein the antireflective coating is disposed in the cavities and not in the spaces between the cavities.

41. An encapsulating sheet according to claim 38, wherein two anti-reflective coatings are provided, one on each side of the encapsulating sheet.

42. (canceled)

43. A method of manufacturing an encapsulating sheet for an organic light-emitting display, the method comprising: forming a plurality of cavities in one side of a transparent sheet of material for receiving organic light-emitting structures; and coating at least one side of the transparent sheet of material with an anti-reflective coating for reducing reflection of light from said at least one side.

44. A method according to claim 43, comprising depositing the antireflective coating on the side of the transparent sheet having the plurality of cavities therein after forming the cavities.

45. A method according to claim 44, comprising depositing the antireflective coating in the cavities and not in the spaces between the cavities.

46. A method according to claim 43, comprising providing two anti-reflective coatings, one on each side of the encapsulating sheet.
